(19) United States
(12) Patent Application Publication
(10) Pub. No.: US 2025/0248073 A1
(43) Pub. Date: Jul. 31, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Jung-Chien CHENG, Tainan City (TW); Guan-Lin CHEN, Baoshan Township (TW); Shi-Ning JU, Hsinchu City (TW); Kuo-Cheng CHIANG, Zhubei City (TW); Chih-Hao WANG, Baoshan Township (TW)

(73) Assignee: Taiwan Semiconductor Manufacturing Company, Ltd., Hsinchu (TW)

(21) Appl. No.: 18/643,789

(22) Filed: Apr. 23, 2024

Related U.S. Application Data
(60) Provisional application No. 63/624,938, filed on Jan. 25, 2024.

(51) Int. Cl. H01L 29/786; H01L 29/06; H01L 29/423; H01L 29/66; H01L 29/775

(52) U.S. Cl. CPC H10D 30/6757; H10D 30/014; H10D 30/031; H10D 30/43; H10D 30/6735; H10D 62/121; H10D 64/017

(57) ABSTRACT

Semiconductor structures and methods for forming the same are provided. The semiconductor structure includes a plurality of first nanostructures over a substrate, and a plurality of second nanostructures adjacent to the first nanostructures. The semiconductor structure includes a protective layer over the first nanostructures, and a first gate structure formed on the first nanostructures. The semiconductor structure includes a second gate structure formed on the second nanostructures. The semiconductor structure includes a first dielectric wall between the first gate structure and the second gate structure, and a top surface of the first dielectric wall is higher than a top surface of the protective layer.

### CROSS REFERENCE TO RELATED APPLICATIONS

This Application claims the benefit of U.S. Provisional Application No. 63/624,938, filed on Jan. 25, 2024, the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1Z show perspective views of intermediate stages of forming a semiconductor structure, in accordance with some embodiments.

FIGS. 1ZA to 1ZB show perspective views of intermediate stages of forming a semiconductor structure, in accordance with some embodiments.

FIG. 1B-T shows a diagrammatic top view of the inter-medium stage of the semiconductor structure, and the block A1 shown in FIG. 1B-T corresponds to the structure shown in FIG. 1B, in accordance with some embodiments.

FIG. 1F-T shows a diagrammatic top view of the inter-medium stage of the semiconductor structure, and the block A1 shown in FIG. 1F-T corresponds to the structure shown in FIG. 1F, in accordance with some embodiments.

FIG. 1M-T shows a diagrammatic top view of the inter-medium stage of the semiconductor structure, and the block Bi shown in FIG. 1M-T corresponds to the structure shown in FIG. 1M, in accordance with some embodiments.

FIG. 2 shows a cross-sectional representation of the semiconductor structure shown along the line B-B′ in FIG. 1ZB, in accordance with some embodiments.

FIG. 3 shows a cross-sectional representation of the semiconductor structure shown along the line C-C′ in FIG. 1ZB, in accordance with some embodiments.

FIGS. 4A-4B show cross-sectional representations of a semiconductor structure, in accordance with some embodiments.

FIGS. 5A-5B show cross-sectional representations of a semiconductor structure, in accordance with some embodiments.

FIGS. 6A-6B show cross-sectional representations of a semiconductor structure, in accordance with some embodiments.

FIG. 7 show cross-sectional representations of a semiconductor structure, in accordance with some embodiments.

FIG. 8 show cross-sectional representations of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structure includes first nanostructures structure and second nanostructures formed over a substrate. The protective layers are formed on the first nanostructures and the second nanostructures to protect the first nanostructures and the second nanostructures. A gate structure is formed on the nanostructures, and a first spacer layer and a second spacer layer are formed on opposite sidewall surfaces of the gate structure. A dielectric wall is between the first nanostructures structure and the second nanostructures. Since a portion of the gate electrode layer of the gate structure is replaced with the dielectric wall, the area of the gate electrode layer is reduced. The unwanted capacitance between gate structure and the S/D contact structure of the semiconductor structure is reduced. In addition, due to the protection of the protective layer, each of the nanostructures has the substantially the same thickness. When the uniformity of thickness of each of the nanostructures is improved, the performance of the semiconductor structure is improved. The source/drain (S/D) structure or S/D region(s) may refer to a source or a drain, individually or collectively dependent upon the context.

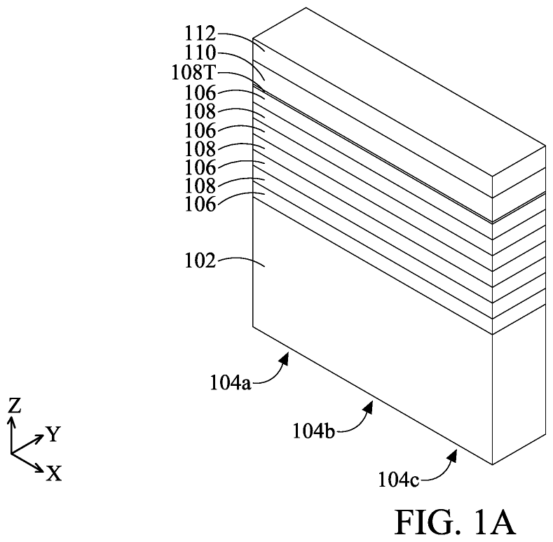

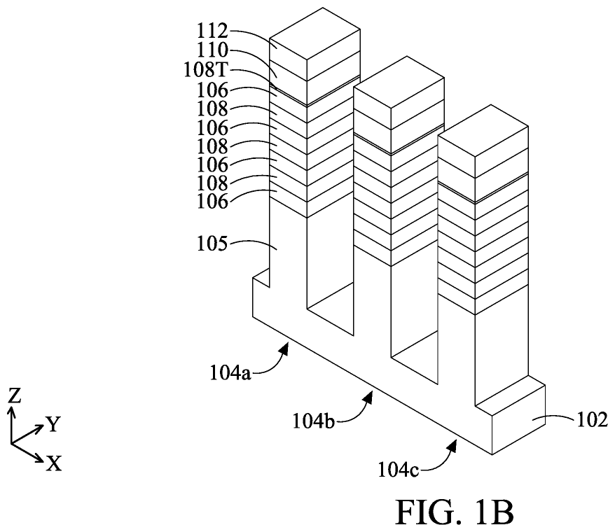

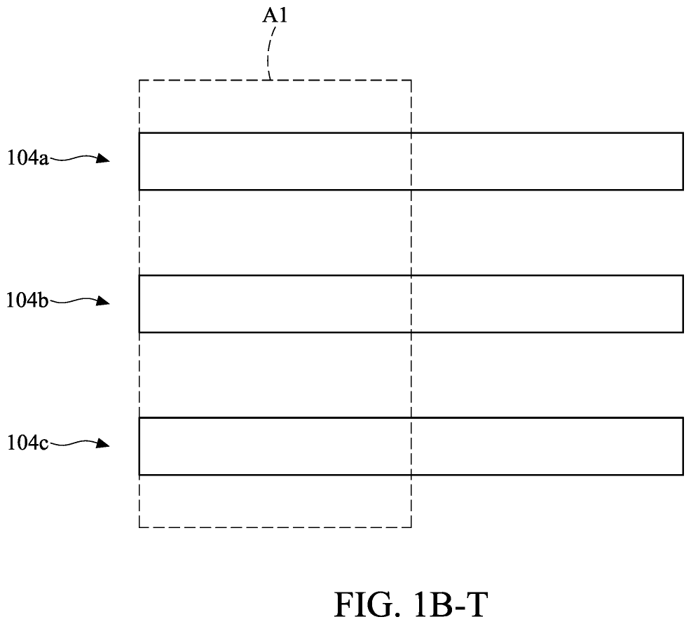

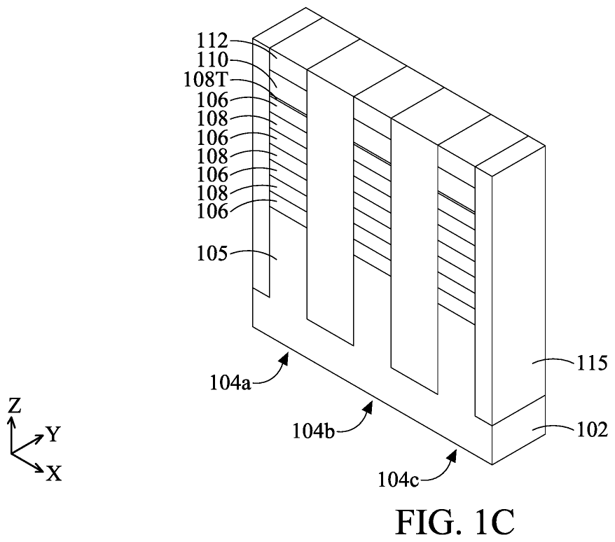

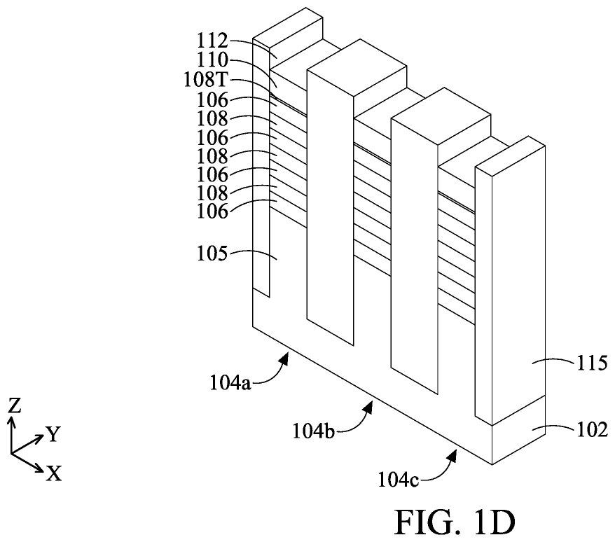

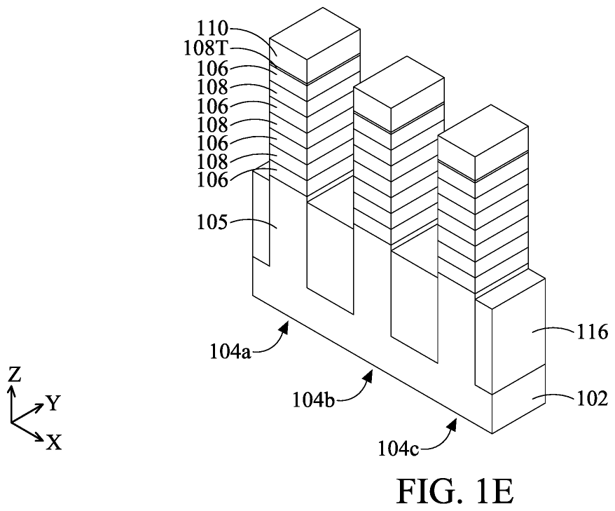

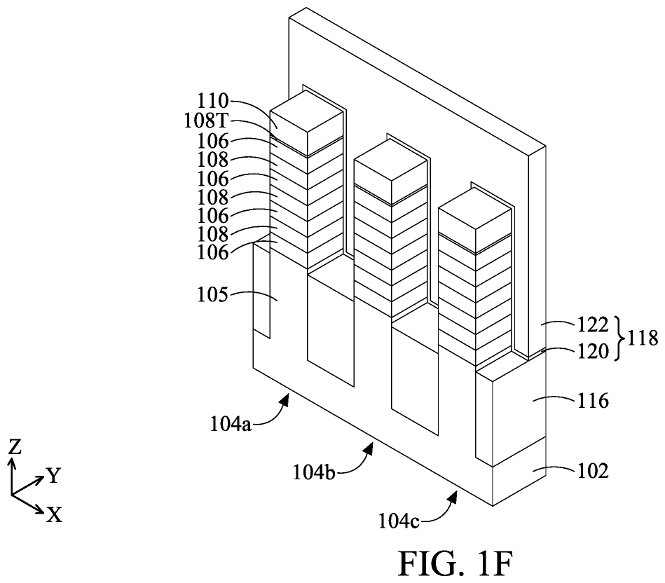

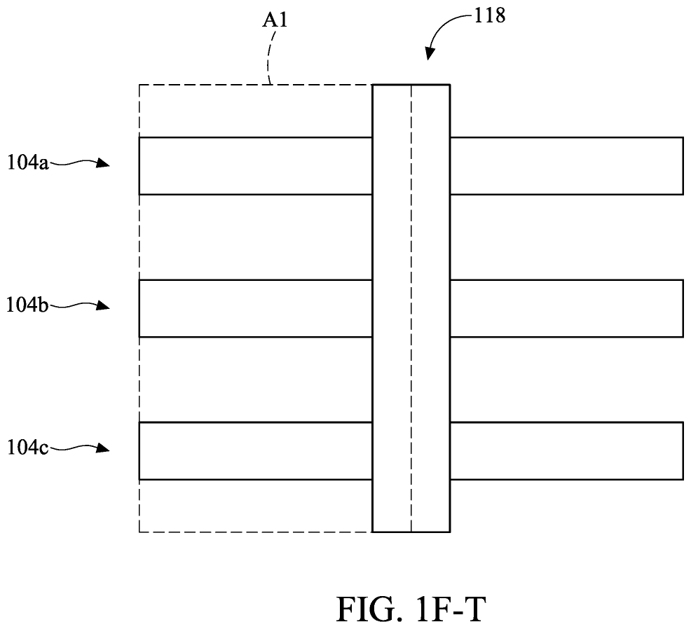

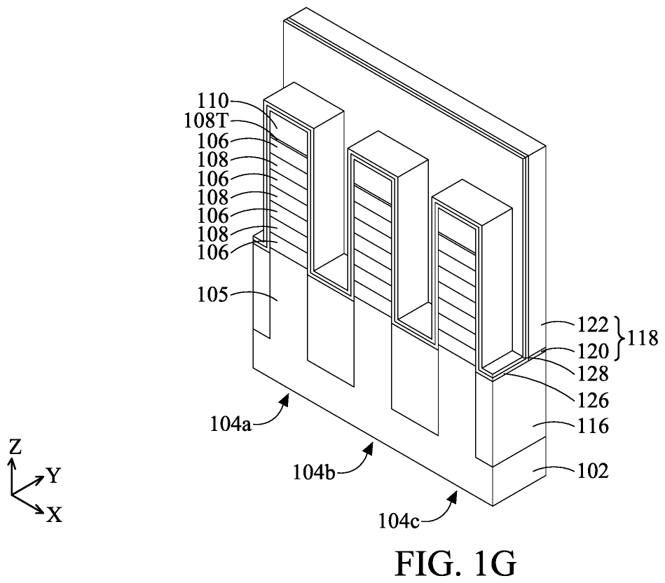

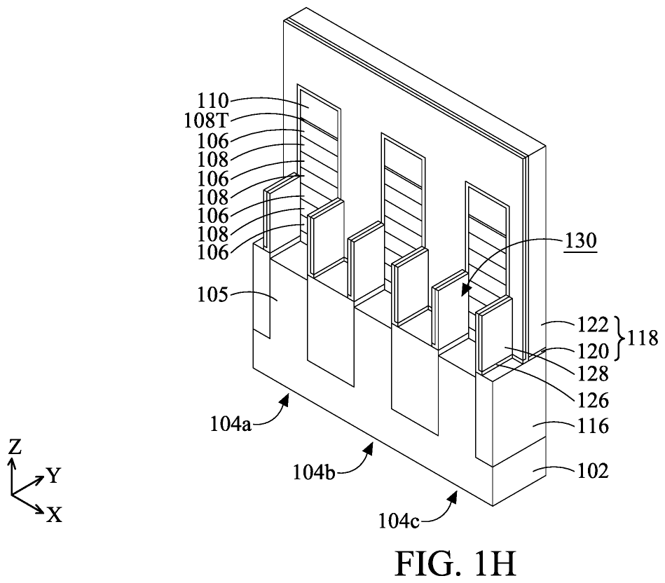

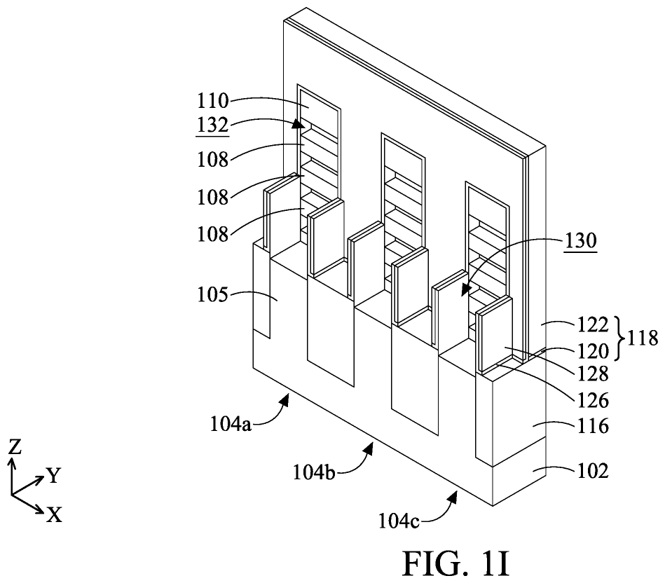

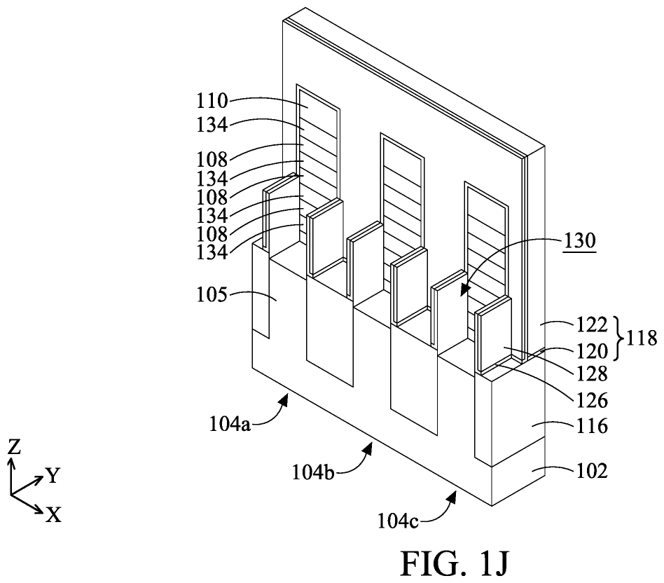

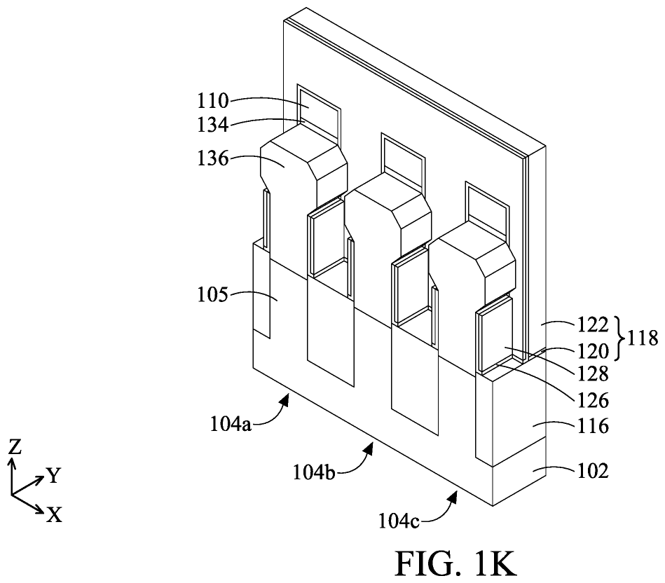

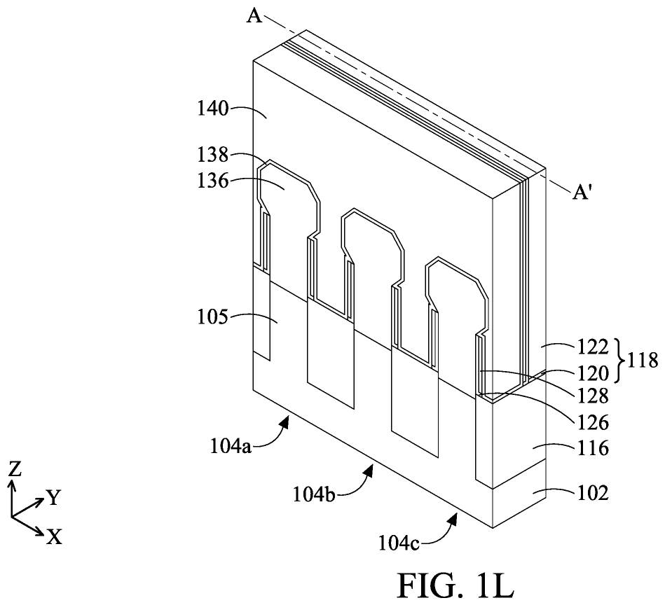

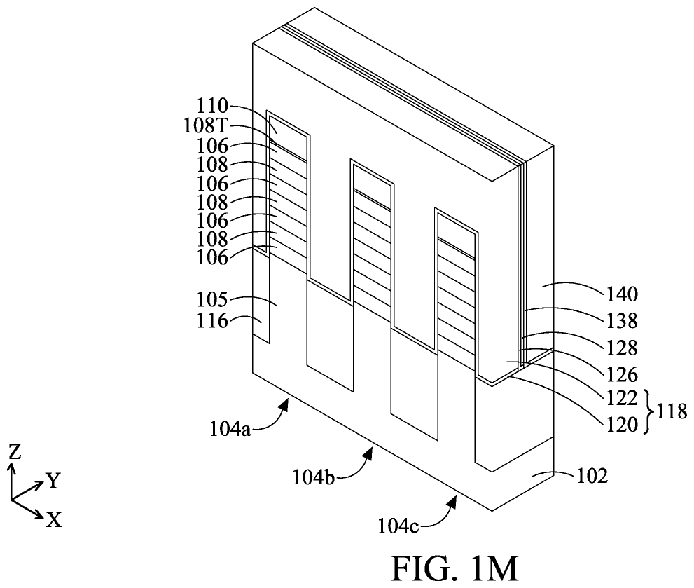

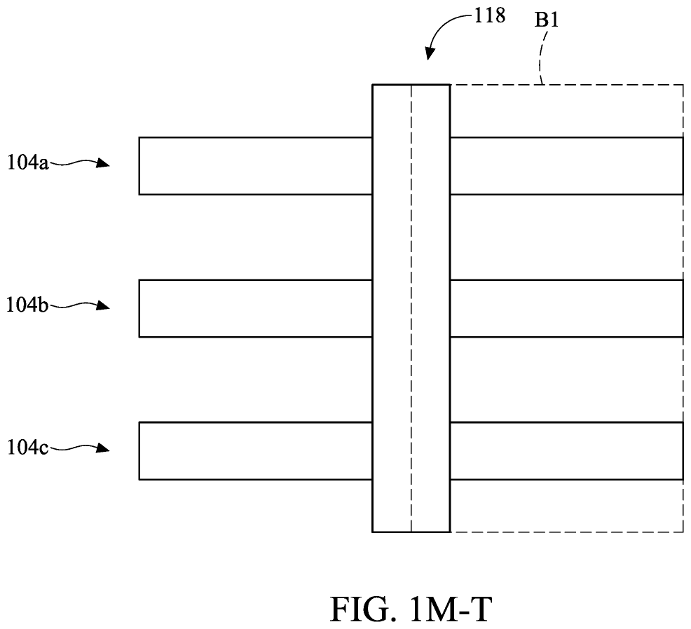

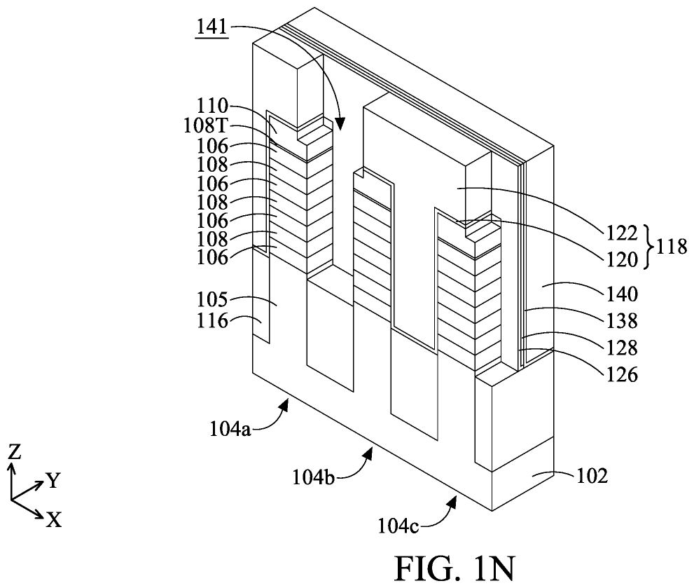

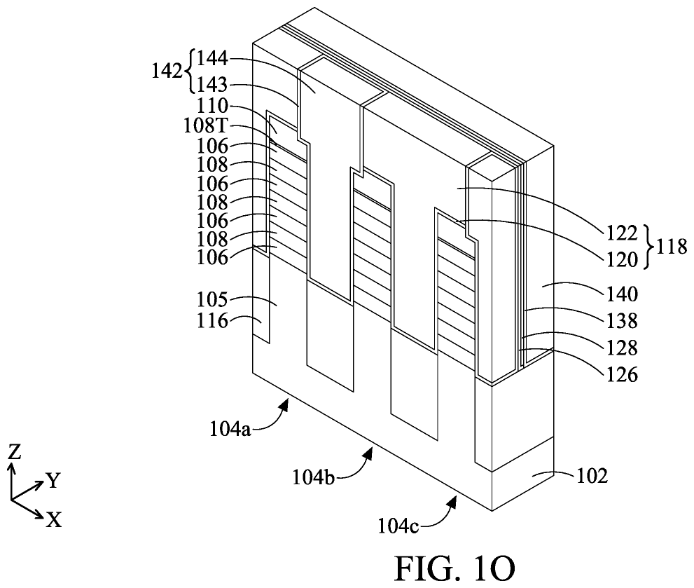

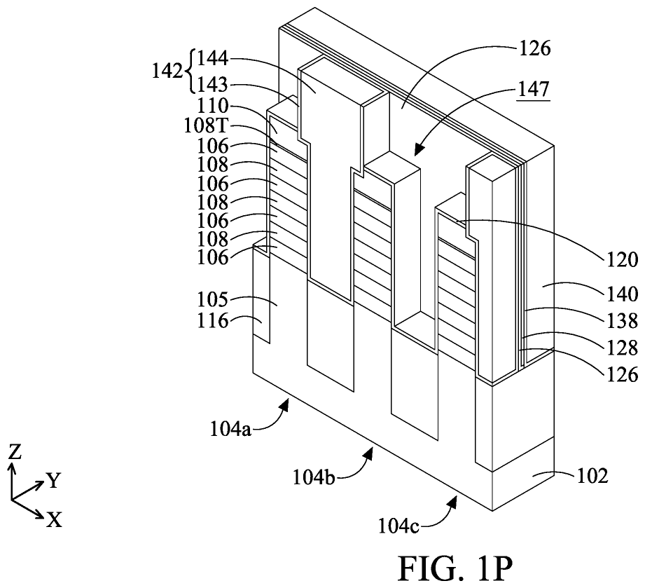

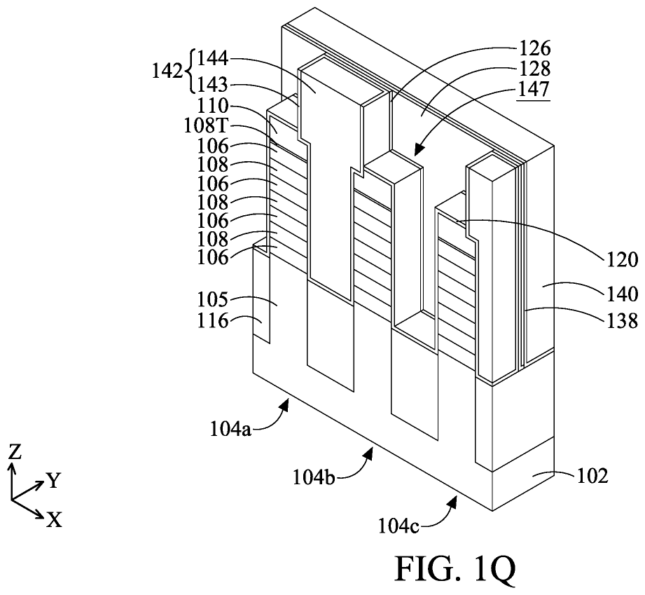

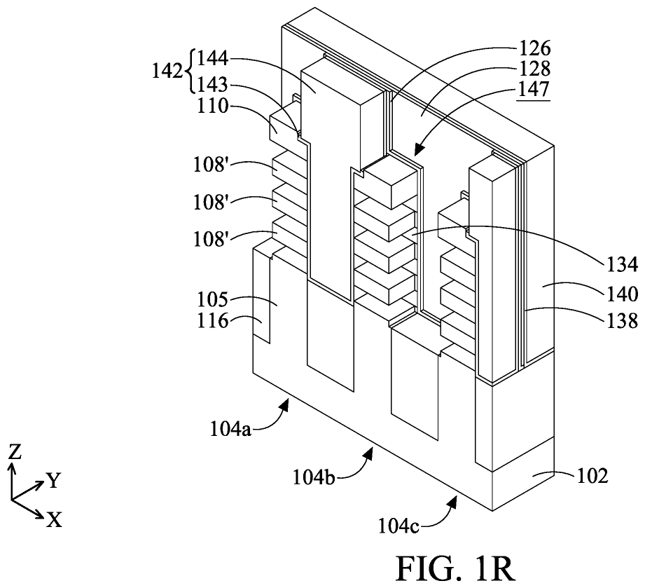

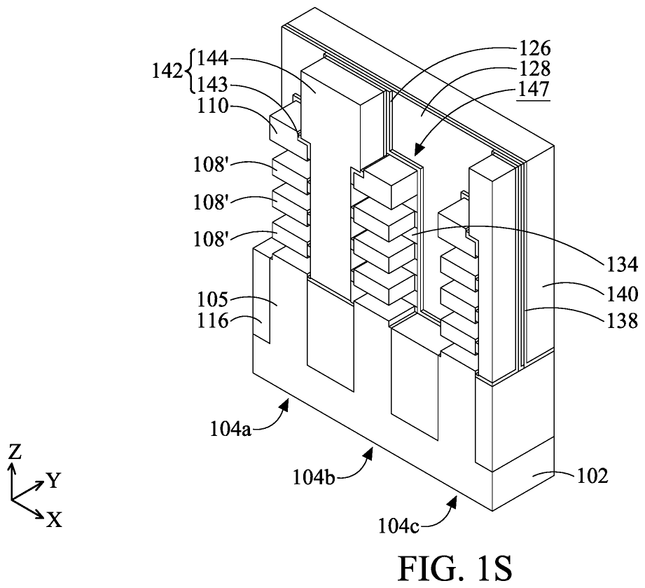

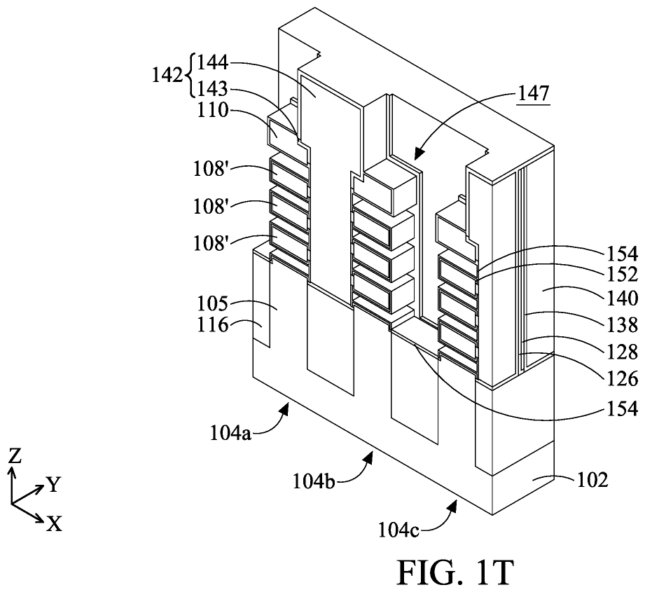

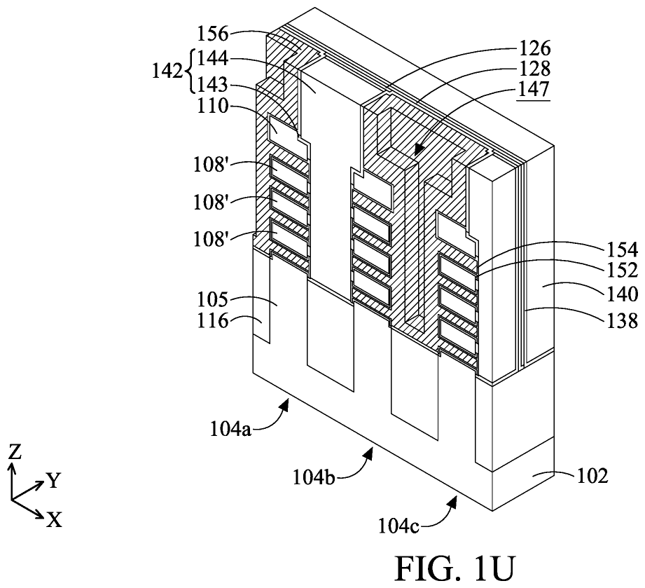

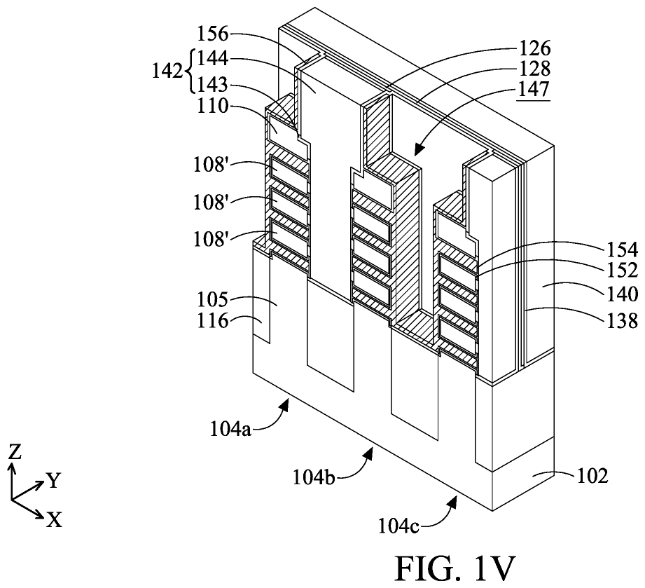

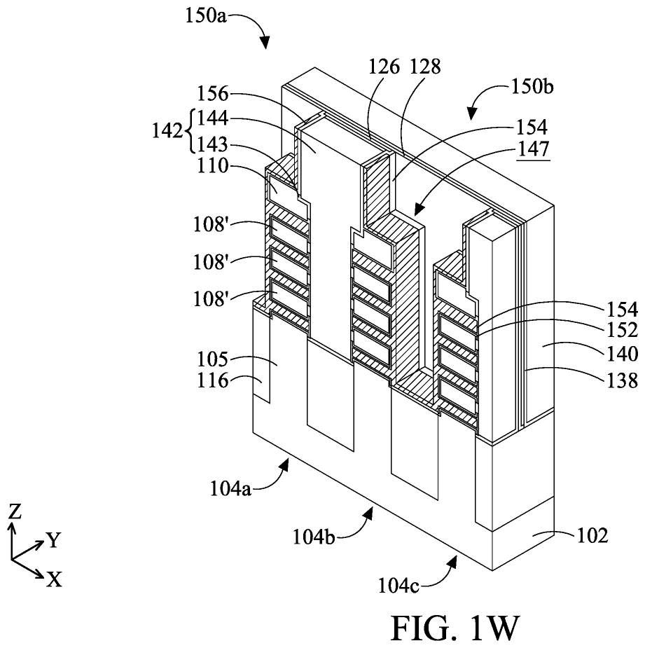

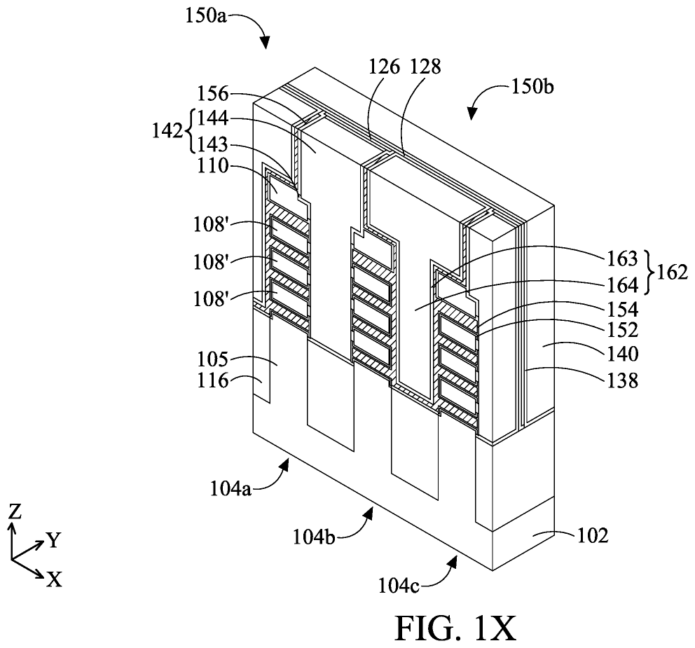

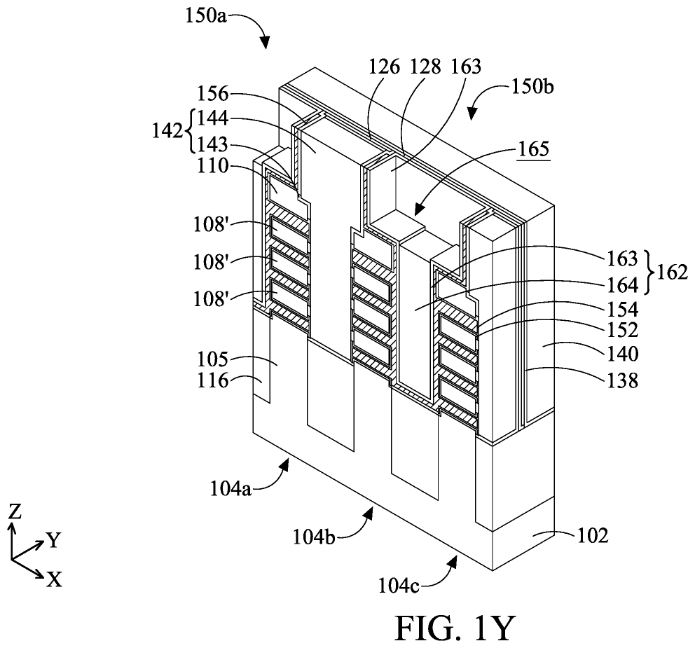

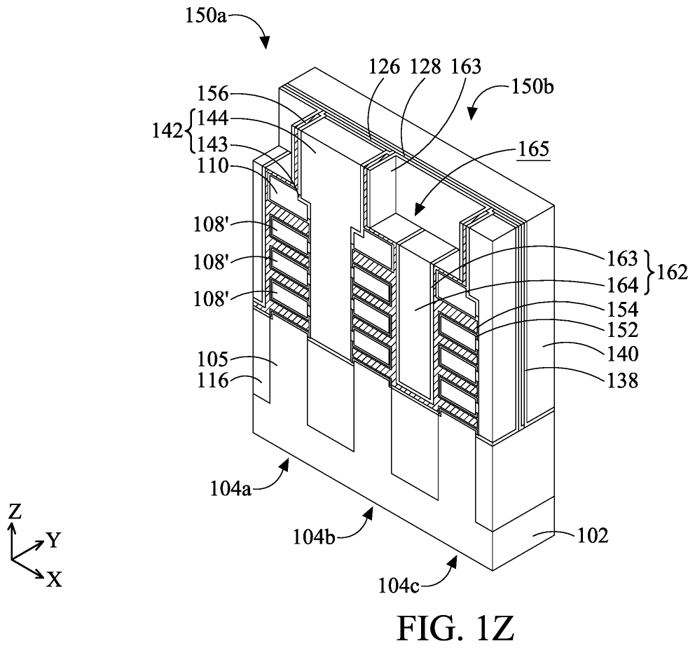

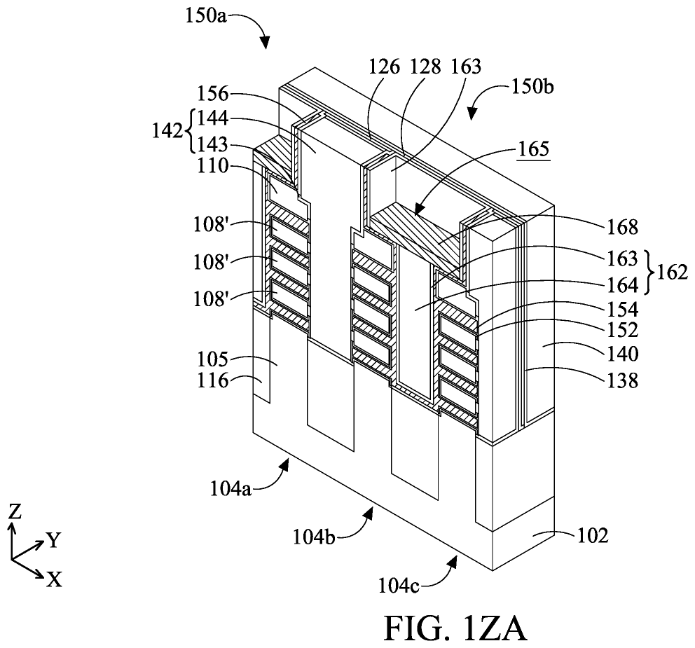

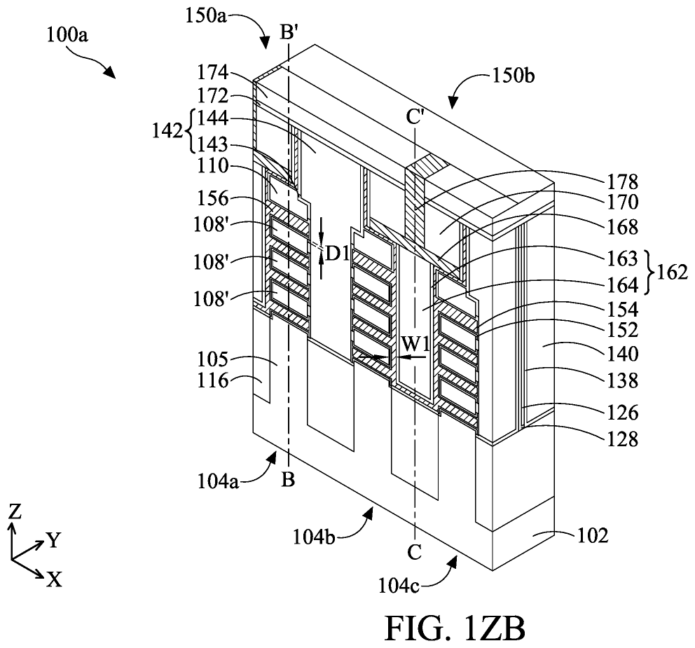

FIGS. 1A to 1ZB show perspective views of intermediate stages of forming a semiconductor structure 100a, in accordance with some embodiments.

As shown in FIG. 1A, first semiconductor material layers 106 and second semiconductor material layers 108 are formed along a first direction (e.g. x-axis) over a substrate 102. Next, a protective layer 110 and a hard mask layer 112 are formed on the stack of the first semiconductor material layers 106 and second semiconductor material layers 108. The second semiconductor material layers 108 includes the topmost second semiconductor material layer 108T. The thickness of the topmost second semiconductor material layer 108T is smaller than the thickness of the other second semiconductor material layer 108. The topmost second semiconductor material layer 108T will be removed along with the first semiconductor material layers 106 at the step of FIG. 1R since the thickness of the topmost second semiconductor material layer 108T is very small.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor layer 106 is made of silicon germanium (SiGe), and the second semiconductor layer 108 is made of silicon (Si).

In some embodiments, the first semiconductor layers 106 and the second semiconductor layers 108 independently include silicon (Si), germanium (Ge), silicon germanium (SiGe), indium arsenide (InAs), indium gallium arsenide (InGaAs), indium antimonide (InSb), or another applicable material.

The first semiconductor layers 106 and the second semiconductor layers 108 are made of different materials having different lattice constant. In some embodiments, the first semiconductor layer 106 is made of silicon (Si), and the second semiconductor layer 108 is made of silicon germanium (SiGe).

In some embodiments, each of the first semiconductor layer 106 has a thickness in a range from about 3 nm to about 8 nm. In some embodiments, each of the second semiconductor layer 108 has a thickness in a range from about 3 nm to about 8 nm. In some embodiments, the topmost second semiconductor material layer 108T has a thickness in a range from about 1 nm to about 2 nm.

It should be noted that although four first semiconductor material layers 106 and four second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

The protective layer 110 with respect to the first semiconductor material layers 106 has a high etching selectivity. When the first semiconductor material layers 106 are removed, the protective layer 110 will not be removed in step of FIG. 1R. In some embodiments, the protective layer 110 is made of silicon nitride (SiN), silicon carbon nitride (SiCN), silicon oxycarbide (SiOC), silicon oxycarbonitride (SiOCN), and another applicable material. The protective layer 110 may be formed by thermal oxidation or chemical vapor deposition (CVD), such as low-temperature chemical vapor deposition (LPCVD) or plasma-enhanced CVD (PECVD). In some embodiments, the protective layer 110 has a thickness in a range from about 2 nm to about 20 nm. In some embodiments, the thickness of the protective layer 110 is greater than the thickness of the first semiconductor material layer 106 and the thickness of second semiconductor material layer 108.

In some embodiments, the hard mask layer 112 is made of silicon nitride (SiN), and is formed by chemical vapor deposition (CVD), such as low-temperature chemical vapor deposition (LPCVD) or plasma-enhanced CVD (PECVD).

Afterwards, as shown in FIG. 1B, the hard mask layer 112 is patterned to form a patterned hard mask layer 112, and the protective layer 110 is then patterned by using the patterned hard mask layer 112 as a mask, in accordance with some embodiments. After the protective layer 110 is patterned, the semiconductor material stack is patterned to form fin structures 104a/104b/104c, in accordance with some embodiments. In some embodiments, the fin structures 104a/104b/104c include a base fin structure 105 and the semiconductor material stack of the first semiconductor material layers 106 and the second semiconductor material layers 108.

FIG. 1B-T shows a diagrammatic top view of the inter-medium stage of the semiconductor structure 100a, and the block A1 shown in FIG. 1B-T corresponds to the structure shown in FIG. 1B, in accordance with some embodiments.

The hard mask layer 112 and the protective layer 110 are patterned by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process includes a dry etching process or a wet etching process.

Afterwards, as shown in FIG. 1C, after the fin structures 104a/104b/104c are formed, an isolation material 115 is formed on the hard mask layer 112 and the protective layer 110, in accordance with some embodiments. Next, a planarization process is performed on the isolation material 115 until the hard mask layer 112 is exposed. As a result, the top surface of the isolation material 115 is substantially coplanar with the top surface of the hard mask layer 112. In some embodiments, the planarization process includes CMP process.

In some embodiments, the isolation material 115 is made of silicon oxide, silicon nitride, silicon oxynitride (SiON), another suitable insulating material, or a combination thereof. In some embodiments, the isolation material 115 is formed by chemical vapor deposition (CVD), atomic layer deposition (ALD), physical vapor deposition (PVD), another suitable method, or a combination thereof.

Next, as shown in FIG. 1D, the hard mask layer 112 is removed to expose the protective layer 110, in accordance with some embodiments. In some embodiments, the hard mask layer 112 is removed by an etching process, such as dry etching or wet etching.

Afterwards, as shown in FIG. 1E, after the hard mask layer 112 is removed, the top portion of the isolation material 115 is removed to form an isolation structure 116, in accordance with some embodiments. The top surface of the isolation structure 116 is lower than the top surface of the fin structures 104a/104b/104c.

The isolation structure 116 is configured to electrically isolate active regions (e.g. the fin structures 104a/104b/104c) of the semiconductor structure 100a and is also referred to as shallow trench isolation (STI) feature in accordance with some embodiments.

In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

As shown in FIG. 1F, after the isolation structure 116 is formed, dummy gate structure 118 is formed across the fin structures 104a/104b/104c and extend over the isolation structure 116, in accordance with some embodiments. The dummy gate structure 118 may be used to define the source/drain (S/D) regions and the channel regions of the resulting semiconductor structure 100a. The dummy gate structure 118 is formed along the Y-axis.

FIG. 1F-T shows a diagrammatic top view of the inter-medium stage of the semiconductor structure 100a, and the block A1 shown in FIG. 1F-T corresponds to the structure shown in FIG. 1F, in accordance with some embodiments.

In some embodiments, the dummy gate structure 118 includes a dummy gate dielectric layer 120 and a dummy gate electrode layer 122. In some embodiments, the dummy gate dielectric layer 120 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 120 is formed using thermal oxidation, chemical vapor deposition (CVD), atomic layer deposition (ALD), physical vapor deposition (PVD), another suitable method, or a combination thereof.

In some embodiments, the dummy gate electrode layer 122 includes polycrystalline-silicon (poly-Si), poly-crystalline silicon-germanium (poly-SiGe), metallic nitrides, metallic silicides, metals, or a combination thereof. In some embodiments, the dummy gate electrode layer 122 is formed using chemical vapor deposition (CVD), physical vapor deposition (PVD), or a combination thereof.

The formation of the dummy gate structure 118 may include conformally forming a dielectric material as the dummy gate dielectric layers 120. Afterwards, a conductive material may be formed over the dielectric material as the dummy gate electrode layers 122, and the hard mask layer (not shown) may be formed over the conductive material. Next, the dielectric material and the conductive material may be patterned through the hard mask layer (not shown) to form the dummy gate structure 118.

As shown in FIG. 1G, after the dummy gate structure 118 is formed, a first gate spacer layer 126 and a second gate spacer layer 128 are formed along and covering opposite sidewalls of the dummy gate structure 118 and covering opposite sidewalls of the source/drain regions of the fin structures 104a/104b/104c, in accordance with some embodiments.

The first gate spacer layer 126 and the second gate spacer layer 128 may be configured to separate source/drain (S/D) structures from the dummy gate structure 118 and support the dummy gate structure 118. The first gate spacer layer 126 and the second gate spacer layer 128 may be configured to constrain a lateral growth of subsequently formed source/drain structure and support the fin structures 104a/104b/104c.

The first gate spacer layer 126 and the second gate spacer layer 128 are made of different materials. The second gate spacer layer 128 has a high etching selectivity with respect to the first gate spacer layer 126. When the first gate spacer layer 126 is removed by an etching process, the second gate spacer layer 128 is not removed by the etching process.

In some embodiments, the first gate spacer layer 126 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the second gate spacer layer 128 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof.

In some embodiments, the thickness of the first gate spacer layer 126 is in a range from about 1 nm to about 5 nm. In some embodiments, the thickness of the second gate spacer layer 128 is in a range from about 1 nm to about 5 nm.

The formation of the first gate spacer layer 126 and the second gate spacer layer 128 may include conformally depositing a dielectric material covering the dummy gate structure 118, the protective layer 110, the fin structures 104a/104b/104c, and the isolation structure 116 over the substrate 102, and performing an anisotropic etching process, such as dry plasma etching, to remove the dielectric layer covering the top surfaces of the dummy gate structure 118, the protective layer 110, and portions of the isolation structure 116.

Next, as shown in FIG. 1H, after the first gate spacer layer 126 and the second gate spacer layer 128 are formed, the source/drain (S/D) regions of the fin structures 104a/104b/104c are recessed to form source/drain (S/D) recesses 130, in accordance with some embodiments. More specifically, the first semiconductor material layers 106 and the second semiconductor material layers 108 not covered by the dummy gate structure 118, the first gate spacer layer 126 and the second gate spacer layer 128 are removed, in accordance with some embodiments.

In some embodiments, the fin structures 104a/104b/104c are recessed by performing an etching process. The etching process may be an anisotropic etching process, such as dry plasma etching, and the dummy gate structure 118, the first gate spacer layer 126 and the second gate spacer layer 128 are used as etching masks during the etching process. In some embodiments, the first gate spacer layer 126 and the second gate spacer layer 128 in the S/D regions are also recessed to form the lowered first gate spacer layer 126 and the lowered second gate spacer layer 128.

Afterwards, as shown in FIG. 1I, the first semiconductor material layers 106 exposed by the S/D recesses 130 are laterally recessed to form notches 132, in accordance with some embodiments.

In some embodiments, an etching process is performed on the semiconductor structure 100a to laterally recess the first semiconductor material layers 106 of the fin structures 104a/104b/104c from the source/drain recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Afterwards, as shown in FIG. 1J, inner spacer layers 134 are formed in the notches 132 between the second semiconductor material layers 108, in accordance with some embodiments. In some embodiments, the inner spacer layers 134 and the protective layer 110 are made of different materials since the protective layer 110 and the inner spacer layers 134 are made in different steps.

The inner spacer layers 134 are configured to separate the source/drain structures and the gate structures formed in subsequent manufacturing processes in accordance with some embodiments.

In some embodiments, the inner spacer layers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layers 134 are formed by a deposition process, such as chemical vapor deposition (CVD) process, atomic layer deposition (ALD) process, another applicable process, or a combination thereof.

Next, as shown in FIG. 1K, after the inner spacers 134 are formed, source/drain (S/D) structures 136 are formed in the S/D recess 130, in accordance with some embodiments. The topmost surface of the protective layer 110 is higher than the topmost surface of the S/D structure 136. In addition, the bottommost surface of the protective layer 110 is higher than the topmost surface of the S/D structure 136.

In some embodiments, the S/D structures 136 are formed using an epitaxial growth process, such as Molecular beam epitaxy (MBE), Metal-organic Chemical Vapor Deposition (MOCVD), Vapor-Phase Epitaxy (VPE), another applicable epitaxial growth process, or a combination thereof. In some embodiments, the S/D structures 136 are made of any applicable material, such as Ge, Si, GaAs, AlGaAs, SiGe, GaAsP, SiP, SiC, SiCP, or a combination thereof.

In some embodiments, the S/D structures 136 are in-situ doped during the epitaxial growth process. For example, the S/D structures 136 may be the epitaxially grown SiGe doped with boron (B). For example, the S/D structures 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the S/D structures 136 are doped in one or more implantation processes after the epitaxial growth process.

Afterwards, as shown in FIG. 1L, after the S/D structures 136 are formed, an etch stop layer 138 is conformally formed to cover the S/D structures 136 and an interlayer dielectric (ILD) layer 140 is formed over the contact etch stop layers 138, in accordance with some embodiments.

In some embodiments, the etching stop layer 138 is made of a dielectric material, such as silicon nitride, silicon oxide, silicon oxynitride, another suitable dielectric material, or a combination thereof. The dielectric material for the etching stop layer 138 may be conformally deposited over the semiconductor structure by performing chemical vapor deposition (CVD), ALD, other application methods, or a combination thereof. In some embodiments, the etching stop layer 138 has a thickness in a range from about 1 nm to about 5 nm.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the etching stop layer 138 and the ILD layer 140 are deposited, a planarization process such as CMP or an etch-back process may be performed until the gate electrode layer 120 of the dummy gate structure 118 is exposed, as shown in FIG. 11, in accordance with some embodiments.

FIGS. 1M-1ZB show perspective views of the semiconductor structure 100a along the dummy gate structure 118 along line A-A′ in FIG. 1I, in accordance with some embodiments. FIG. 1M-T shows a diagrammatic top view of the inter-medium stage of the semiconductor structure 100a, and the block Bi shown in FIG. 1M-T corresponds to the structure shown in FIG. 1M, in accordance with some embodiments.

As shown in FIG. 1M, the dummy gate structure 118 including the dummy gate dielectric layer 120 and the dummy gate electrode layer 122 is formed on the fin structures 104a/104b/104c, in accordance with some embodiments.

Next, as shown in FIG. 1N, a portion of the dummy gate structure 118 is removed to form a trench 141, in accordance with some embodiments. More specifically, a top portion of the dummy gate electrode layer 122 and a portion of the dummy gate dielectric layer 120 are removed by using the protective layer 110 as the etching stop layer. In addition, a portion of the protective layer 110 may be removed. In some other embodiments, the protective layer 110 is not removed.

When the portion of the dummy gate electrode layer 122 is removed, the fin structures 104a/104b/104c protected by the protective layer 110 are not removed. As a result, the top surface of the isolation structure 116 is exposed. In addition, the sidewall surfaces of the fin structures 104a/104b/104c are exposed. Since the protective layer 110 protects the underlying layers, the trench 141 is self-aligned formed. If no protective layer on the fin structures 104a/104b/104c, the fin structures 104a/104b/104c may be damaged during the etching process for forming the trench 141 due to the overlay shift (misalignment) of the photolithography. The overlay shift (misalignment) is resolved by formation of the protective layer 110.

Afterwards, as shown in FIG. 10, a liner layer 143 and a filling layer 144 are filled into the trench 141, in accordance with some embodiments. A dielectric wall 142 is constructed by the liner layer 143 and the filling layer 144. The liner layer 143 is in direct contact with the protective layer 110, the first semiconductor layers 106 and the second semiconductor layers 108 of the fin structures 104a/104b/104c.

It should be noted that the dielectric wall 142 is between two adjacent fin structures, specifically the fin structure 104a and the fin structure 104b. In addition, the dielectric wall 142 penetrates through the protective layer 110. The protective layer 110 is in direct contact with the liner layer 143 of the dielectric wall 142. The dielectric wall 142 has a top portion and a bottom portion, and the top portion is wider than the bottom portion. The dielectric wall 142 has a T-shaped structure. Since the portion of the protective layer 110 is removed as shown in FIG. 1N, a portion of the dielectric wall 142 is embedded in the protective layer 110.

In some embodiments, the liner layer 143 is made of Silicon oxide (SiO), silicon nitride (SiN), silicon carbon nitride (SiCN), silicon oxycarbide (SiOC), silicon oxide carbonitride (SiOCN), or applicable material. In some embodiments, the liner layer 143 is formed by chemical vapor deposition (CVD), physical vapor deposition, (PVD), atomic layer deposition (ALD), or other applicable processes.

In some embodiments, the filling layer 144 is made of silicon nitride (SiN), silicon carbon nitride (SiCN), silicon oxycarbide (SiOC), silicon oxide carbonitride (SiOCN), or a combination thereof. In some embodiments, the filling layer 144 is formed by chemical vapor deposition (CVD), physical vapor deposition, (PVD), atomic layer deposition (ALD), or other applicable processes.

Next, as shown in FIG. 1P, another portion of the dummy gate electrode layer 122 of the dummy gate structure 118 is removed to form a trench 147, in accordance with some embodiments. As a result, a portion of the first gate spacer layer 126 is exposed by the trench 147.

More specifically, the portion of the gate electrode layer 122 is removed by the removal process. As a result, a portion of the dummy gate dielectric layer 120 is exposed. It should be noted that the dielectric wall 142 including the liner layer 143 and the filling layer 144 are not removed when the portion of the dummy gate structure 118 is removed.

The removal process may include one or more etching processes. For example, when the dummy gate electrode layers 122 are polysilicon, a wet etchant such as a tetramethylammonium hydroxide (TMAH) solution may be used to selectively remove the dummy gate electrode layers 122.

Afterwards, as shown in FIG. 1Q, the exposed first gate spacer layer 126 is removed to expose a portion the second gate spacer layer 128, in accordance with some embodiments. After the removal process, the outer sidewall surface of the first gate spacer layer 126 is substantially level with the outer sidewall surface of the dummy gate dielectric layer 122. In some embodiments, the exposed first gate spacer layer 126 is removed by an etching process, such as dry etching process or wet etching process.

Next, as shown in FIG. 1R, the exposed dummy gate dielectric layer 120 is removed, in accordance with some embodiments. Afterwards, the first semiconductor material layers 106 are removed to form nanostructures 108′ with the second semiconductor material layers 108, in accordance with some embodiments.

The topmost second semiconductor material layer 108T will be removed along with the first semiconductor material layers 106 since the thickness of the topmost second semiconductor material layer 108T is smaller than the other second semiconductor material layer 108. As a result, the top surface, bottom surface and the sidewall surface of the protective layer 110 are exposed. The dummy gate dielectric layer 120 may be removed using a plasma dry etching, a dry chemical etching, and/or a wet etching.

It should be noted that when the first semiconductor material layers 106 are removed, the protective layer 110 is not removed since the protective layer 110 with respect to the first semiconductor material layers 106 has a high etching selectivity.

The nanostructures 108′ are used as the channel layers of the semiconductor structure 100a. The S/D structure 136 is attached to the nanostructures 108′. In addition, a portion of the liner layer 143 is exposed when the first semiconductor material layers 106 are removed.

It should be noted that after the exposed dummy gate dielectric layer 120 is removed, the outer sidewall surface of the first gate spacer layer 126 extends beyond the sidewall surfaces of the protective layer 110 and the sidewall surfaces of the nanostructures 108′. Therefore, there is a gap between the outer sidewall surface of the first gate spacer layer 126 and the outer sidewall surface of the protective layer 110. In other words, the first gate spacer layer 126 protrudes from the top surface and sidewall surface of the protective layer 110. There is a step height between the first gate spacer layer 126 and the protective layer 110.

The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions. In some embodiments, the upper portions of the gate spacer layers 126 are also removed.

Next, as shown in FIG. 1S, after the nanostructures 108′ are formed, the exposed portion of the liner layer 143 is removed, in accordance with some embodiments. The remaining liner layer 143 is between and in direct contact with the nanostructures 108′ and the filling layer 144. The liner layer 143 has several separated portions which are not connected to each other after the exposed portion of the liner layer 143 is removed.

Afterwards, as shown in FIG. 1T, an interfacial layer 152 is formed to surround the nanostructures 108′, and then a gate dielectric layer 154 is formed on the interfacial layer 152, the isolation structure 116, the dielectric wall 142 and the protective layer 110, in accordance with some embodiments. More specifically, the gate dielectric layer 154 is in direct contact with the protective layer 110, the dielectric wall 142, the isolation structure 116 and the interfacial layer 152. In other words, the protective layer 110 is surrounded by the gate dielectric layer 154. The gate dielectric layer 154 is in direct contact with the liner layer 143 of the dielectric wall 142.

It should be noted that gate dielectric layer 154 is conformally formed on interfacial layer 152, the isolation structure 116, the dielectric wall 142 and the protective layer 110, and therefore the trench 147 is not completely filled with the gate dielectric layer 154. The trench 147 is still remaining. Note that the gate dielectric layer 154 is in direct contact with the filling layer 144 of the dielectric wall 142. In addition, the gate dielectric layer 154 is in direct contact with the sidewall surfaces of the protective layer 110.

In addition, since the first gate spacer layer 126 protrudes from the top surface and sidewall surface of the protective layer 110, as mentioned in FIG. 1R, the gate dielectric layer 154 directly on the first gate spacer layer 126 still protrudes from the gate dielectric layer 154 directly on the protective layer 110. The gap is still remaining due to the step height between the first gate spacer layer 126 and the protective layer 110.

In some embodiments, the interfacial layers 152 are oxide layers formed around the nanostructures 108′ and on the top of the base fin structure 105. In some embodiments, the interfacial layers 152 are formed by performing a thermal process.

In some embodiments, the gate dielectric layer 154 is formed over the interfacial layers 152, so that the nanostructures 108′ are surrounded (e.g. wrapped) by the gate dielectric layer 154. In addition, the gate dielectric layer 154 also covers the sidewalls of the first gate spacer layer 126 and the second gate spacer layer 128 in accordance with some embodiments.

In some embodiments, the gate dielectric layer 154 is made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layer 154 is formed using chemical vapor deposition (CVD), atomic layer deposition (ALD), another applicable method, or a combination thereof.

Next, as shown in FIG. 1U, a gate electrode layer 156 is formed on the gate dielectric layer 154, in accordance with some embodiments. A gate structure 150 is constructed by the interfacial layer 152, the gate dielectric layer 154 and the gate electrode layer 156. It should be noted that the gate electrode layer 156 is conformally formed on the gate dielectric layer 154, and therefore the trench 147 is still left and not filled with the gate electrode layer 156.

In some embodiments, the gate electrode layer 156 is formed on the gate dielectric layer 154. In some embodiments, the gate electrode layer 156 is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layer 156 is formed using chemical vapor deposition (CVD), atomic layer deposition (ALD), electroplating, another applicable method, or a combination thereof.

Other conductive layers, such as work function metal layers, may also be formed in the gate structures 150, although they are not shown in the figures. In some embodiments, the function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr), molybdenum nitride, tungsten nitride (WN), ruthenium (Ru) or a combination thereof.

Afterwards, as shown in FIG. 1V, a portion of the gate electrode layer 156 is removed, in accordance with some embodiments. As a result, the trench 147 has a T-shaped structure after the portion of the gate electrode layer 156 is removed. The outer sidewall surface of the gate electrode layer 156 is substantially level with the outer sidewall surface of the gate dielectric layer 154 since the gap between the outer sidewall surface of the first gate spacer layer 126 and the outer sidewall surface of the protective layer 110 is created at the step of FIG. 1 R. In other words, the outer sidewall surface of the gate electrode layer 156 can be substantially coplanar with the outer sidewall surface of the gate dielectric layer 154 due to the step height between the first gate spacer layer 126 and the protective layer 110. Therefore, the removal amount of the gate electrode layer 156 can be controlled by the defining the step height between the first gate spacer layer 126 and the protective layer 110.

In some embodiments, the portion of the gate electrode layer 156 is removed by an etching process, such as dry etching or wet etching.

It should be noted that in order to reduce the unwanted capacitor between the gate electrode layer 156 and the S/D contact structure, the area of the gate electrode layer 156 is reduced by removing a portion of the gate electrode layer 156.

Next, as shown in FIG. 1W, the exposed portion of the gate dielectric layer 154 is removed to expose the second gate spacer layer 128, in accordance with some embodiments. After the exposed portion of the gate dielectric layer 154 is removed, the trench 147 is still left. The second gate spacer layer 128 is exposed by the trench 147. In some embodiments, the exposed portion of the gate dielectric layer 154 is removed by an etching process, such as dry etching or wet etching.

It should be noted that the outer sidewall surface of the gate electrode layer 156 is substantially level with the outer sidewall surface of the gate dielectric layer 154 since the gap between the outer sidewall surface of the first gate spacer layer 126 and the outer sidewall surface of the protective layer 110 is created at the step of FIG. 1 R.

The gate structure 150 includes a first gate structure 150a and a second gate structure 150b. The first gate structure 150a is separated from the second gate structure 150b by the dielectric wall 142. The first gate structure 150a and the second gate structure 150b are formed on opposite sidewall surfaces of the dielectric wall 142.

The first gate structure 150a includes the interfacial layer 152 surrounding the nanostructures 108′ of the first fin structure 104a, and the gate dielectric layer 154 formed on the interfacial layer 152, and the gate electrode layer 156 formed on the gate dielectric layer 154. The second gate structure 150b includes the interfacial layer 152 surrounding the nanostructures 108′ of the second fin structure 104b and the third fin structure 104c, and the gate dielectric layer 154 formed on the interfacial layer 152, and the gate electrode layer 156 formed on the gate dielectric layer 154.

Afterwards, as shown in FIG. 1X, a liner layer 163 and a filling layer 164 are filled into the trench 147, in accordance with some embodiments. A dielectric wall 162 is constructed by the liner layer 163 and the filling layer 164. The liner layer 163 is in direct contact with the gate electrode layer 156. The liner layer 163 is used to prevent the gate electrode layer 156 from being oxidated by the filling layer 164. The liner layer 163 and the filling layer 164 are made of different materials.

It should be noted that the dielectric wall 162 is between two adjacent fin structures 104b and 104c. The dielectric wall 162 has a top portion and a bottom portion, and the top portion is wider than the bottom portion. The dielectric wall 162 has a T-shaped structure.

In some embodiments, the liner layer 163 is made of silicon nitride (SiN), silicon carbon nitride (SiCN), silicon oxide carbonitride (SiOCN) or another applicable material. In some embodiments, the liner layer 163 is formed by chemical vapor deposition (CVD), physical vapor deposition, (PVD), atomic layer deposition (ALD), or other applicable processes. In some embodiments, the liner layer 163 has a thickness in a range from about 1 nm to about 10 nm.

In some embodiments, the filling layer 164 is made of silicon oxide (SiO), silicon nitride (SiN), silicon carbon nitride (SiCN), silicon oxycarbide (SiOC), silicon oxide carbonitride (SiOCN), or a combination thereof. In some embodiments, the filling layer 164 is formed by chemical vapor deposition (CVD), physical vapor deposition, (PVD), atomic layer deposition (ALD), or other applicable processes.

Next, as shown in FIG. 1Y, the top portion of the filling layer 164 of the dielectric wall 162 is removed to form a recess 165, in accordance with some embodiments. As a result, a portion of the liner layer 163 is exposed by the recess 165. The topmost surface of the filling layer 164 of the dielectric wall 162 is higher than the top surface of the protective layer 110.

In some embodiments, the portion of the filling layer 164 of the dielectric wall 162 is removed by an etching process, such as dry etching process or wet etching process.

Afterwards, as shown in FIG. 1Z, the horizontal portion of the liner layer 163 of the dielectric wall 162 is removed, in accordance with some embodiments. As a result, the vertical portion of the gate electrode layer 156 is exposed by the recess 165. It should be noted that the horizontal portion of the liner layer 163 directly on the gate electrode layer 156 is removed to expose the gate electrode layer 156, but the sidewall portion of the liner layer 163 is still on the gate electrode layer 156.

In some embodiments, the horizontal portion of the liner layer 163 of the dielectric wall 162 is removed by an etching process, such as dry etching process or wet etching process.

Next, as shown in FIG. 1ZA, a conductive layer 168 is formed in the recess 165, in accordance with some embodiments. The recess 165 is not completely filled with the conductive layer 168. The conductive layer 168 is in direct contact with and electrically connected to the gate electrode layer 156. The bottom surface of the conductive layer 168 is in direct contact with the gate electrode layer 156, but the sidewall surface of the conductive layer 168 is separated from the gate electrode layer 156 by the liner layer 163.

Note that the conductive layer 168 is selectively formed on by a selectively deposition process, and therefore the conductive layer 168 is selectively formed on the gate electrode layer 156. Although the conductive layer 168 is mainly formed on the surface of the conductive material, the conductive layer 168 may extend to a position which is directly on the top surface of the dielectric wall 162.

The conductive layer 168 and the gate electrode layer 156 are made of different materials. There is an interface between the conductive layer 168 and the gate electrode layer 156.

In some embodiments, the conductive layer 168 is made of a conductive material including aluminum (Al), copper (Cu), tungsten (W), titanium (Ti), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. In some embodiments, the conductive layer 168 is made of tungsten (W) free from fluorine (F).

The conductive layer 168 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition process.

Afterwards, as shown in FIG. 1ZB, the dielectric layer 170 is formed on the conductive layer 168 and in the recess 165, in accordance with some embodiments. Next, a planarization process such as CMP or an etch-back process may be performed. Next, an etching stop layer 172 is formed on the dielectric wall 162, the protective layer 110 and the dielectric layer 170, and a dielectric layer 174 is formed on the etching stop layer 172, in accordance with some embodiments.

In some embodiments, the dielectric layer 170 is made of silicon oxide, silicon nitride, silicon oxynitride, or applicable dielectric materials. The dielectric layer 170 may be formed by chemical vapor deposition (CVD), physical vapor deposition, (PVD), atomic layer deposition (ALD), or other applicable processes.

In some embodiments, the etching stop layer 172 is made of a dielectric material, such as silicon nitride, silicon oxide, silicon oxynitride, another suitable dielectric material, or a combination thereof. The dielectric material for the etching stop layer 172 may be conformally deposited over the semiconductor structure by performing chemical vapor deposition (CVD), ALD, other application methods, or a combination thereof.

The dielectric layer 174 may include multilayers made of multiple dielectric materials, such as silicon oxide, silicon nitride, silicon oxynitride, phosphosilicate glass (PSG), borophosphosilicate glass (BPSG), or another applicable low-k dielectric materials. The dielectric layer 174 may be formed by chemical vapor deposition (CVD), physical vapor deposition, (PVD), atomic layer deposition (ALD), or other applicable processes.

Next, a gate contact structure 178 is formed on the conductive layer 168. The gate contact structure 178 penetrates through the dielectric layer 170 and in direct contact with the conducive layer 168. The gate contact structure 178 is electrically connected to the gate electrode layer 156 by the conductive layer 168.

In some embodiments, the gate contact structure 178 is made of a conductive material including aluminum (Al), copper (Cu), tungsten (W), titanium (Ti), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof.

The gate contact structure 178 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition process.

As shown in FIG. 1ZB, the first gate structure 150a is separated from the second gate structure 150b by the dielectric wall 142. The first gate structure 150a and the second gate structure 150b are formed on opposite sidewall surfaces of the dielectric wall 142. The top surface of the first gate structure 150a is substantially coplanar with the top surface of the dielectric wall 142. The top surface of the second gate structure 150b is substantially coplanar with the top surface of the dielectric wall 142.

The gate electrode layer 156 of the second gate structure 150b extends from the first position to the second position. The first position is on the nanostructures 108′ of the second fin structure 104b, and the second position is on the nanostructures 108′ of the third fin structure 104c. The portion of the gate electrode layer 156 of the second gate structure 150b is directly below the dielectric wall 162.

The top surface of the dielectric wall 142 is higher than the top surface of the protective layer 110. In addition, the top surface of the dielectric wall 162 is higher than the top surface of the protective layer 110. The top surface of the dielectric wall 162 is lower than the top surface of the dielectric wall 142. The top surface of the dielectric wall 162 is lower than the topmost surface of the gate electrode layer 156 of the first gate structure 150a and the second gate structure 150b.

If no protective layer 110 is formed on the nanostructures 108′, when the step for removing a portion of the gate electrode layer 156 by a CMP process, the uniformity of the height of the gate electrode layer 156 is bad due to the CMP process variation. If the height of the gate electrode layer 156 is designed high enough to reduce the impact of the CMP process variation, another unwanted capacitance issue may occur. In order to improve the uniformity of the height and prevent the unwanted capacitance issue, the protective layer 110 is formed on the nanostructures 108′.

Furthermore, if no protective layer 110 is formed on the nanostructures 108′, the topmost nanostructure 108′ may be slight removed, and the thickness of the topmost nanostructure 108′ is different from the thickness of the second topmost nanostructure 108′. As a result, the performance of the semiconductor structure 100a may be reduced. Therefore, the protective layer 110 is formed on the nanostructures 108′, and the protective layer 110 can protect the underlying the nanostructures 108′ from being etching during manufacturing process to maintain the thickness of each of the nanostructures 108′. Due to the protection of the protective layer 110, each of the nanostructures 108′ has the substantially the same thickness. When the uniformity of thickness of each of the nanostructures 108′ is improved, the performance of the semiconductor structure 100a is improved.

The protective layer 110 is configured to protect the underlying nanostructures 108′ from being etched or damaged. The gate dielectric layer 154 and the gate electrode layer 156 are formed on the protective layer 110. The topmost surface of the gate electrode layer 156 is higher than the top surface of the protective layer 110.

A shown in FIG. 1ZB, there is a first width W1 between an end of the gate electrode layer 156 and an end of the nanostructures 108′ along the horizontal direction. In some embodiments, the first width W1 is in a range from about 2 nm to about 12 nm.

If the thickness of the first width W1 is smaller than 2 nm, the threshold voltage (Vth) of the semiconductor structure 100a is difficult to control. If the thickness of the first width W1 is larger than 12 nm, the area of the gate electrode layer 156 is too large, and the unwanted capacitance between the nanostructures 108′ of the second fin structure 104b and the nanostructures 108′ of the third fin structure 104c may increase. In other words, the portion of the gate electrode layer 156 between the nanostructures 108′ of the second fin structure 104b and the nanostructures 108′ of the third fin structure 104c is replaced with the dielectric wall 162. Therefore, the area of the gate electrode layer 156 is reduced to reduce unwanted capacitance between the nanostructures 108′ of the second fin structure 104b and the nanostructures 108′ of the third fin structure 104c. In addition, the unwanted capacitance between the gate electrode layer 156 and the contact on the S/D structure 136 can be reduced. Therefore, the performance of the semiconductor structure 100a is improved.

There is a first recessed distance D1 of the gate dielectric layer 154 is measured from the top surface of the interfacial layer 152 and the top surface of the liner layer 143. In some embodiments, the first recessed distance D1 of the gate dielectric layer 154 is in a range from about 0.1 nm to about 5 nm. When the first recessed distance D1 of the gate dielectric layer 154 is within the above-mentioned range, the coverage of the gate dielectric layer 154 on the nanostructures 108′ is increased, and the control ability of the gate structure 150 is improved. Therefore, the performance of the semiconductor structure 100a is improved.

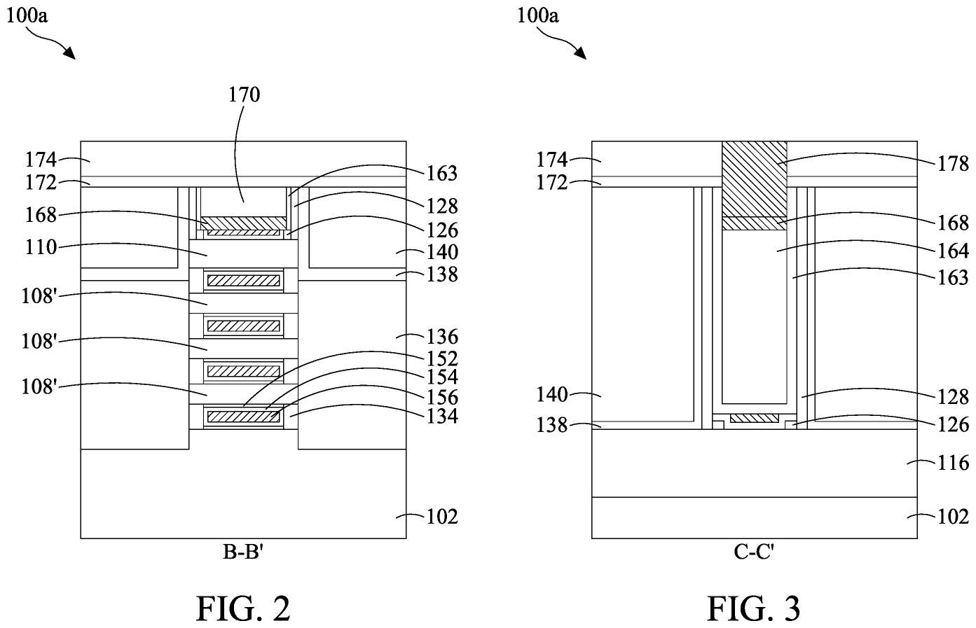

FIG. 2 shows a cross-sectional representation of the semiconductor structure 100a shown along the line B-B′ in FIG. 1ZB, in accordance with some embodiments.

As shown in FIG. 2, there is a second width W2 between the two adjacent second spacer layers 128. The second width W2 is obtained by the performing the step of FIG. 1Q, the exposed first gate spacer layer 126 is removed to expose a portion the second gate spacer layer 128. Since the main portion of the first spacer layer 126 is removed, the remaining first spacer layer 126 is left below the liner layer 163 of the dielectric wall 162.

In addition, the bottom surface of the first spacer layer 126 and the bottom surface of the second spacer layer 128 are in direct contact with the top surface of the protective layer 110.

FIG. 3 shows a cross-sectional representation of the semiconductor structure 100a shown along the line C-C′ in FIG. 1ZB, in accordance with some embodiments.

As shown in FIG. 3, the remaining first spacer layer 126 is directly below the dielectric wall 162. The top surface of the second spacer layer 128 is higher than the top surface of the first spacer layer 126. In addition, the top surface of the second spacer layer 128 is higher than the bottom surface of the conductive layer 168.

It should be noted that the second width W2 is between the two adjacent second spacer layers 128. The second width W2 is obtained by the performing the step of FIG. 1Q, the exposed first gate spacer layer 126 is removed to expose a portion the second gate spacer layer 128. Since the main portion of the first spacer layer 126 is removed, the remaining first spacer layer 126 is left below the dielectric wall 162. In addition, the second width W2 is greater than the distance between two adjacent first spacer layers 126.

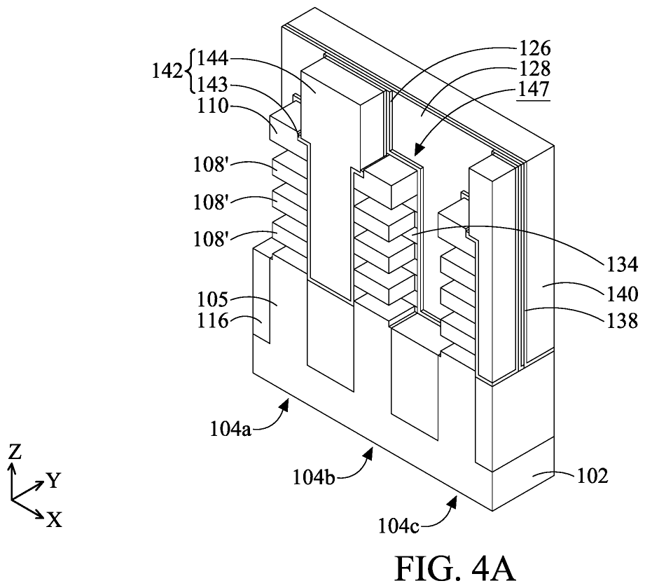

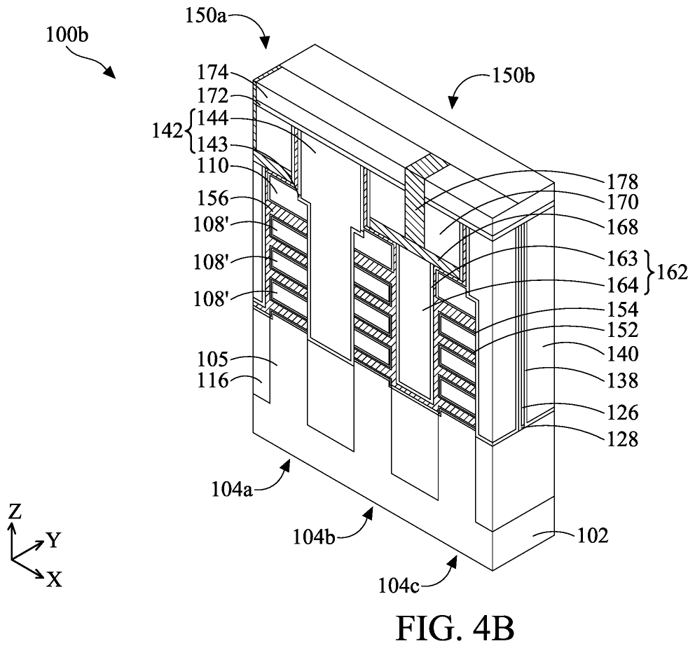

FIGS. 4A-4B show cross-sectional representations of a semiconductor structure 100b, in accordance with some embodiments. The semiconductor structure 100b of FIGS. 4A-4B includes elements that are similar to, or the same as, elements of the semiconductor structure 100a of FIG. 1ZB. Materials and processes for forming the semiconductor structure 100b may be similar to, or the same as, those for forming the semiconductor structure 100a described above and are not repeated herein.

The difference between semiconductor structure 100b of FIG. 4A and the semiconductor structure 100a of FIG. 1R is that the liner layer 143 of the dielectric wall 142 is not removed. The liner layer 143 is a continuous layer and is exposed by the trench 147.

Afterwards, as shown in FIG. 4B, the interfacial layer 152 is formed on the nanostructures 108′, and the gate dielectric layer 154 is formed on the interfacial layer 152. It should be noted that the gate dielectric layer 154 is formed on the sidewall surfaces of the liner layer 143 of the dielectric wall 142. Compared with the semiconductor structure 100a shown in FIG. 1ZB, there is no first recessed distance D1 of the gate dielectric layer 154 is observed in FIG. 4B.

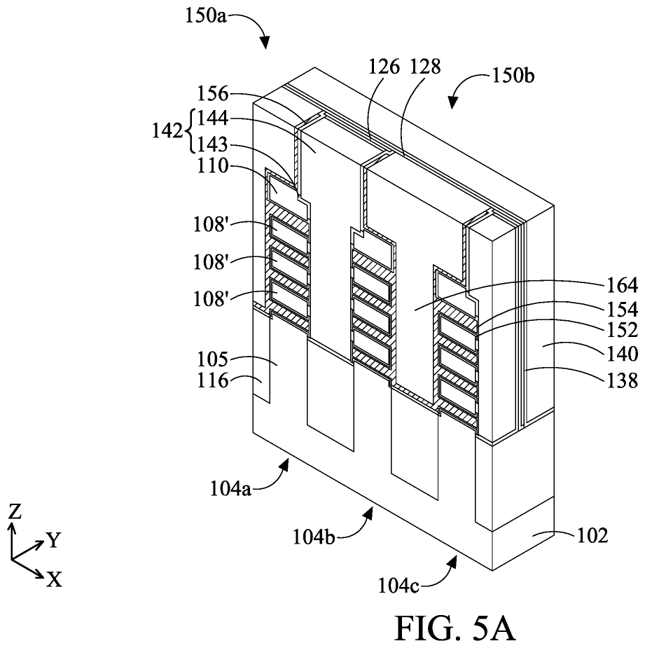

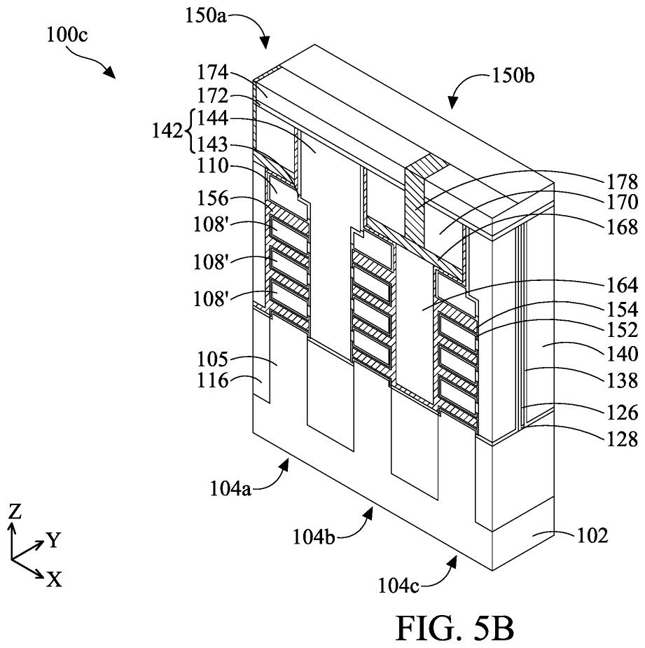

FIGS. 5A-5B show cross-sectional representations of a semiconductor structure 100c, in accordance with some embodiments. The semiconductor structure 100c of FIGS. 5A-5B includes elements that are similar to, or the same as, elements of the semiconductor structure 100a of FIG. 1ZB. Materials and processes for forming the semiconductor structure 100c may be similar to, or the same as, those for forming the semiconductor structure 100a described above and are not repeated herein.

The difference between semiconductor structure 100c of FIG. 5A and the semiconductor structure 100a of FIG. 1S is that no liner layer is formed between the gate electrode layer 156 and the filling layer 164. The dielectric wall 162 is made of the filling layer 164.

Next, as shown in FIG. 5B, the conductive layer 168 is formed on the dielectric wall 162 with the filling layer 164 without the liner layer 163. In addition, the sidewall surfaces of the conductive layer 168 are in direct contact with the gate electrode layer 156, but in FIG. 1ZB, the sidewall surfaces of the conductive layer 168 are not in direct contact with the gate electrode layer 156.

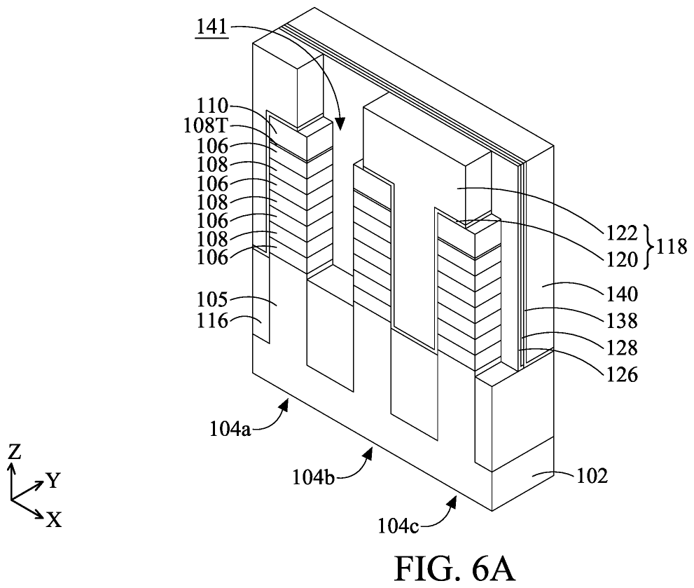

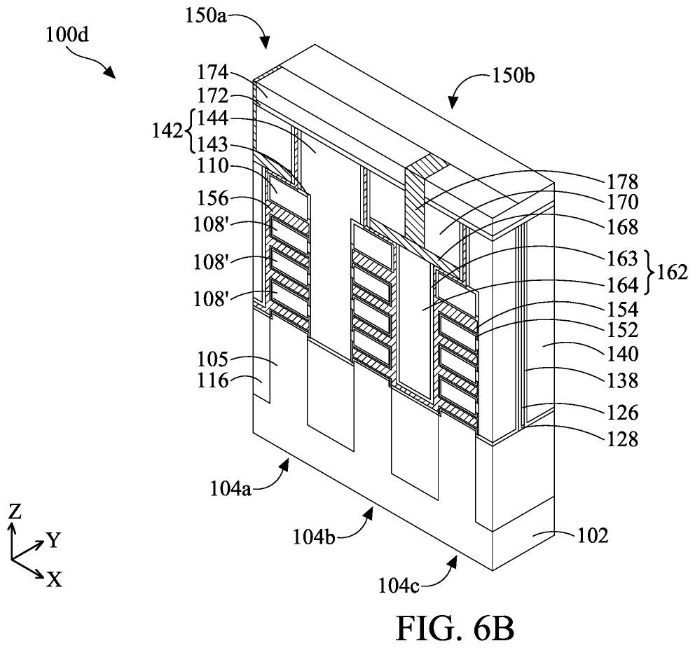

FIGS. 6A-6B show cross-sectional representations of a semiconductor structure 100d, in accordance with some embodiments. The semiconductor structure 100d of FIGS. 6A-6B includes elements that are similar to, or the same as, elements of the semiconductor structure 100a of FIG. 1ZB. Materials and processes for forming the semiconductor structure 100d may be similar to, or the same as, those for forming the semiconductor structure 100a described above and are not repeated herein.

The difference between semiconductor structure 100d of FIG. 6A and the semiconductor structure 100a of FIG. 1N is that the protective layer 110 is not recessed while the dummy gate electrode layer 122 is removed. The protective layer 110 is still has the rectangular-shaped structure.

Afterwards, as shown in FIG. 6B, the dielectric wall 142 is formed in the trench 141. The dielectric wall 142 has a T-shaped structure.

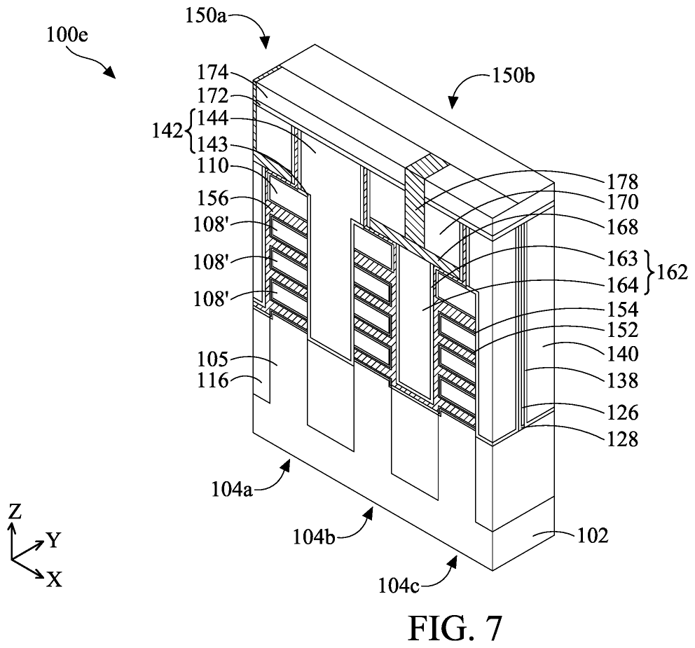

FIG. 7 show cross-sectional representations of a semiconductor structure 100e, in accordance with some embodiments. The semiconductor structure 100e of FIG. 7 includes elements that are similar to, or the same as, elements of the semiconductor structure 100b of FIG. 4B. Materials and processes for forming the semiconductor structure 100e may be similar to, or the same as, those for forming the semiconductor structure 100e described above and are not repeated herein.

The difference between semiconductor structure 100e of FIG. 7 and the semiconductor structure 100b of FIG. 4B is that that the protective layer 110 is not recessed while the dummy gate electrode layer 122 is removed. The protective layer 110 is still has the rectangular-shaped structure.

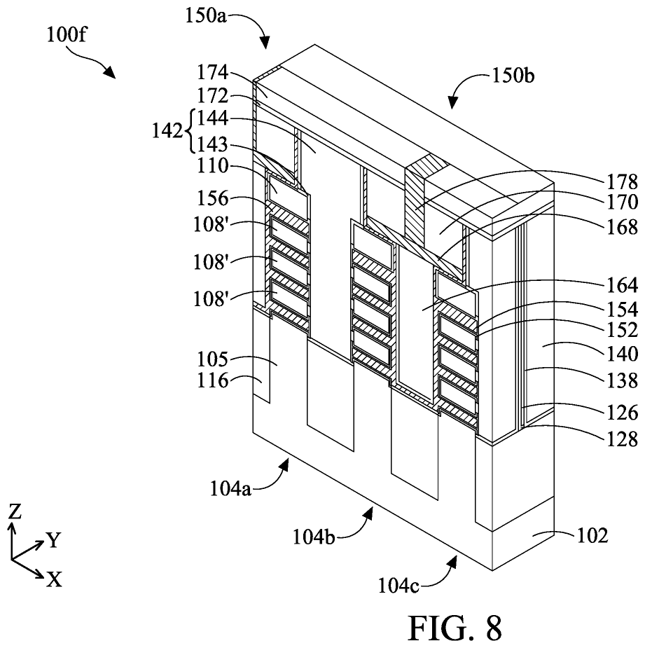

FIG. 8 show cross-sectional representations of a semiconductor structure 100f, in accordance with some embodiments. The semiconductor structure 100f of FIG. 8 includes elements that are similar to, or the same as, elements of the semiconductor structure 100c of FIG. 5B. Materials and processes for forming the semiconductor structure 100f may be similar to, or the same as, those for forming the semiconductor structure 100c described above and are not repeated herein.

The difference between semiconductor structure 100f of FIG. 8 and the semiconductor structure 100b of FIG. 4B is that that the protective layer 110 is not recessed while the dummy gate electrode layer 122 is removed. The protective layer 110 is still has the rectangular-shaped structure.

In order to improve the uniformity of the height of the gate structure 150a/150b and prevent the unwanted capacitance issue, the protective layer 110 is formed on the nanostructures 108′. The protective layer 110 can protect the underlying nanostructures 108′ from being damaged to maintain the thickness of the nanostructures 108′.

In addition, the portion of the gate electrode layer 156 between the nanostructures 108′ of the second fin structure 104b and the nanostructures 108′ of the third fin structure 104c is replaced with the dielectric wall 162. Thus, the area of the gate electrode layer 156 is reduced to reduce unwanted capacitance between the nanostructures 108′ of the second fin structure 104b and the nanostructures 108′ of the third fin structure 104c. Furthermore, the unwanted capacitance between the gate electrode layer 156 and the contact on the S/D structure 136 can be reduced. Therefore, the performance of the semiconductor structure 100a is improved.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. Embodiments of semiconductor structures and methods for forming the same are provided. The semiconductor structure includes first nanostructures structure and second nanostructures formed over a substrate. The protective layers are formed on the first nanostructures and the second nanostructures. A gate structure is formed on the nanostructures, and a first spacer layer and a second spacer layer are formed on opposite sidewall surfaces of the gate structure. A dielectric wall is between the first nanostructures structure and the second nanostructures. Since a portion of the gate electrode layer of the gate structure is replaced with the dielectric wall, the area of the gate electrode layer is reduced. The unwanted capacitor of the semiconductor structure is reduced. In addition, due to the protection of the protective layer, each of the nanostructures has the substantially the same thickness. The uniformity of thickness of each of the nanostructures is improved. Therefore, the performance of the semiconductor structure is improved.

In some embodiments, a semiconductor structure is provided. The semiconductor structure includes a plurality of first nanostructures over a substrate, and a plurality of second nanostructures adjacent to the first nanostructures. The semiconductor structure includes a protective layer over the first nanostructures, and a first gate structure formed on the first nanostructures. The semiconductor structure includes a second gate structure formed on the second nanostructures. The semiconductor structure includes a first dielectric wall between the first gate structure and the second gate structure, and a top surface of the first dielectric wall is higher than a top surface of the protective layer.

In some embodiments, a semiconductor structure is provided. The semiconductor structure includes a plurality of first nanostructures over a substrate, and a plurality of second nanostructures adjacent to the first nanostructures. The semiconductor structure includes a first protective layer over the first nanostructures, and a first gate structure formed on the first nanostructures and the second nanostructures. The semiconductor structure also includes a first dielectric wall between the first nanostructures and the second nanostructures, and a top surface of the first gate structure is higher than a top surface of the first dielectric wall.

In some embodiments, a method for forming a semiconductor structure is provided. The method includes forming a first fin structure and a second fin structure over a substrate, respectively, and the first fin structure includes first semiconductor material layers and second semiconductor material layers alternately stacked, and the second fin structure includes first semiconductor material layers and second semiconductor material layers alternately stacked. The method includes forming a first protective layer on the first fin structure and a second protective layer on the second fin structure, and forming a dummy gate structure across the first fin structure and the second fin structure. The method also includes forming a first spacer layer and a second spacer layer on a sidewall surface of the dummy gate structure, and removing a portion of the dummy gate structure to expose the first spacer layer. The method includes removing a portion of the first spacer layer to expose a portion of the second spacer layer, and removing a portion of the first semiconductor material layers to form first nanostructures and second nanostructures. The method includes forming a gate dielectric layer on the first nanostructures and the second nanostructures, and the gate dielectric layer is on the first spacer layer and the second spacer layer. The method includes forming a gate electrode layer on the gate dielectric layer, and removing a portion of the gate electrode layer. The method includes removing a portion of the gate dielectric layer to expose the second spacer layer, and forming a dielectric wall between the first nanostructures and the second nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of first nanostructures over a substrate;
a plurality of second nanostructures adjacent to the first nanostructures;
a protective layer over the first nanostructures;
a first gate structure formed on the first nanostructures;
a second gate structure formed on the second nanostructures; and
a first dielectric wall between the first gate structure and the second gate structure, wherein a top surface of the first dielectric wall is higher than a top surface of the protective layer.

2. The semiconductor structure as claimed in claim 1, wherein the first gate structure is separated from the second gate structure by the first dielectric wall.

3. The semiconductor structure as claimed in claim 1, further comprising:
a plurality of third nanostructures adjacent to the second nanostructures; and
a second dielectric wall between the second nanostructures and the third nanostructures, wherein a top surface of the second dielectric wall is lower than the top surface of the first dielectric wall.

4. The semiconductor structure as claimed in claim 3, wherein a portion of the second gate structure is directly below the second dielectric wall.

5. The semiconductor structure as claimed in claim 3, further comprising:
a conductive layer formed on the second dielectric wall and the second gate structure; and
a contact structure formed on the conductive layer.

6. The semiconductor structure as claimed in claim 1, wherein the first dielectric wall comprises a liner layer and a filling layer on the liner layer, and the liner layer is in direct contact with the first nanostructures.

7. The semiconductor structure as claimed in claim 6, wherein the first gate structure comprises a gate dielectric layer and a gate electrode layer, and the gate dielectric layer of the first gate structure is in direct contact with the filling layer.

8. The semiconductor structure as claimed in claim 1, wherein the first gate structure is formed on a sidewall surface of the first dielectric wall.

9. The semiconductor structure as claimed in claim 1, wherein the protective layer is in direct contact with the first dielectric wall.

10. The semiconductor structure as claimed in claim 1, wherein a portion of the first dielectric wall is embedded in the protective layer.

11. A semiconductor structure, comprising:
a plurality of first nanostructures over a substrate;
a plurality of second nanostructures adjacent to the first nanostructures;
a first protective layer over the first nanostructures;
a first gate structure formed on the first nanostructures and the second nanostructures; and
a first dielectric wall between the first nanostructures and the second nanostructures, wherein a top surface of the first gate structure is higher than a top surface of the first dielectric wall.

12. The semiconductor structure as claimed in claim 11, further comprising:
a conductive layer formed on the first dielectric wall and the first gate structure; and
a contact structure formed on the conductive layer.

13. The semiconductor structure as claimed in claim 11, wherein a portion of the first gate structure is directly below the first dielectric wall.

14. The semiconductor structure as claimed in claim 11, further comprising:
a plurality of third nanostructures adjacent to the second nanostructures; and
a second dielectric wall between the second nanostructures and the third nanostructures, wherein a top surface of the second dielectric wall is higher than the top surface of the first dielectric wall.

15. The semiconductor structure as claimed in claim 14, further comprising:
a second protective layer formed on the third nanostructures, wherein a portion of the second dielectric wall is embedded in the second protective layer.

16. The semiconductor structure as claimed in claim 11, further comprising:
a first spacer layer adjacent to the first gate structure; and
a second spacer layer formed on the first spacer layer, wherein a portion of the first spacer layer is directly below the first dielectric wall.

17. A method for forming a semiconductor structure, comprising:
forming a first fin structure and a second fin structure over a substrate, respectively, wherein the first fin structure comprises first semiconductor material layers and second semiconductor material layers alternately stacked, and the second fin structure comprises first semiconductor material layers and second semiconductor material layers alternately stacked;
forming a first protective layer on the first fin structure and a second protective layer on the second fin structure;
forming a dummy gate structure across the first fin structure and the second fin structure;
forming a first spacer layer and a second spacer layer on a sidewall surface of the dummy gate structure;
removing a portion of the dummy gate structure to expose the first spacer layer;
removing a portion of the first spacer layer to expose a portion of the second spacer layer;
removing a portion of the first semiconductor material layers to form first nanostructures and second nanostructures;
forming a gate dielectric layer on the first nanostructures and the second nanostructures, wherein the gate dielectric layer is on the first spacer layer and the second spacer layer;
forming a gate electrode layer on the gate dielectric layer;
removing a portion of the gate electrode layer;
removing a portion of the gate dielectric layer to expose the second spacer layer; and
forming a dielectric wall between the first nanostructures and the second nanostructures.

18. The method for forming the semiconductor structure as claimed in claim 17, further comprising:
forming the gate dielectric layer on the protective layer; and
forming the gate electrode layer on the protective layer, wherein a top surface of the gate electrode layer is higher than a top surface of the protective layer.

19. The method for forming the semiconductor structure as claimed in claim 17, further comprising:
removing a top portion of the dielectric wall to expose the gate electrode layer; and
forming a conductive layer on the dielectric wall and the gate electrode layer; and
forming a contact structure on the conductive layer.

20. The method for forming the semiconductor structure as claimed in claim 17, wherein a portion of the gate electrode layer is directly below the dielectric wall.
